(19) United States
(12) Patent Application Publication
(10) Pub. No.: US 2012/0049204 A1
(43) Pub. Date: Mar. 1, 2012

(54) LED MODULE

(75) Inventor: CHIH-MING LAI, Chu-Nan (TW)

(73) Assignee: FOXSEMICON INTEGRATED TECHNOLOGY, INC., Chu-Nan (TW)

(21) Appl. No.: 12/900,497

(22) Filed: Oct. 8, 2010

(30) Foreign Application Priority Data
Aug. 25, 2010 (TW) 99128355

(51) Int. Cl. H01L 33/52

(52) U.S. Cl. 257/88; 257/E33.059

(57) ABSTRACT

An LED module includes an electrically insulating ceramic base with a circuit layer directly coated thereon, a plurality of LED dies directly fixed on the base and electrically connected to the circuit layer; and a packaging structure encapsulating the LED dies.

### BACKGROUND

1. Technical Field

The present disclosure relates to a light emitting diode (LED) module.

2. Description of Related Art

Light-emitting diode (LED) is a highly efficient light source currently used widely in such field as automobiles, screen displays, and traffic light indicators due to their high brightness, long lifespan, and wide color range.

Generally an LED module includes a plurality of LED dies mounted on and electronically connected with a printed circuit board (PCB). A metal plate, such as an aluminum plate or a copper plate, is closely attached to the PCB to remove the heat generated by the LED dies. However, as the PCB is usually made of FR-4, which is produced by glass fiber impregnation into ethoxyline, a thermal resistance of the PCB is very large. The heat generated by the LED dies thus can not be timely transferred to the metal plate for dissipating, which results in significant reductions in the lifespan of the LED module.

What is needed, therefore, is an LED module which can overcome the limitations described.

### BRIEF DESCRIPTION OF THE DRAWINGS

FIG. 1 is a schematic view of an LED module in accordance with a first embodiment of the disclosure.

FIG. 2 is a cross section of the LED module of FIG. 1.

FIG. 3 is a cross section of an LED module according to a second embodiment of the disclosure.

FIG. 4 is a cross section of an LED module according to a third embodiment of the disclosure.

FIG. 5 is a cross section of an LED module according to a fourth embodiment of the disclosure.

FIG. 6 is a cross section of an LED module according to a fifth embodiment of the disclosure.

### DETAILED DESCRIPTION

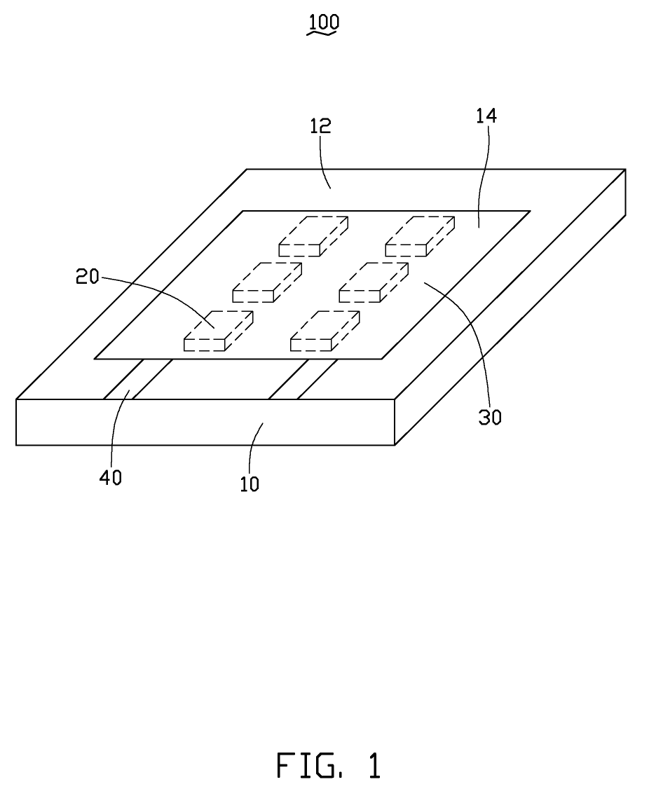

Referring to FIG. 1, an LED module 100 according to a first embodiment of the disclosure is shown. The LED module 100 includes a base 10, a plurality of LED dies 20 fixed on the base 10, a packaging structure 30, and two poles 40.

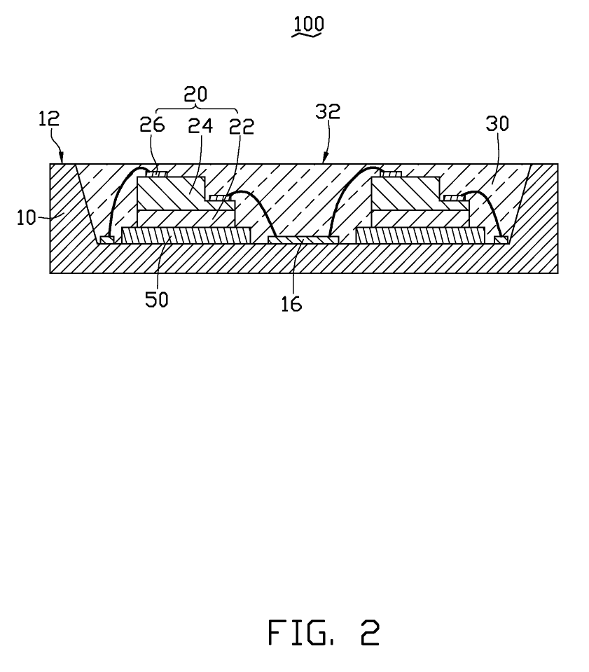

The base 10 is made of a ceramic material of high thermal conductivity, low thermal expansion, and electrical insulation, such as Si₃N₄, SiC, ZrO₂, B₄C, TiB₂, AlxOy, AlN, BeO, Sialon, etc. Referring to FIG. 2, in this embodiment, the base 10 is rectangular and flat. A chamber 14 is concaved from a top side 12 of the base 10 for receiving the LED dies 20 therein.

A circuit layer 16 is directly coated on the base 10 at a bottom of the chamber 14. The circuit layer 16 can be of at least one selected from Ni, Au, Sn, Be, Al, In, Ti, Ta, Ag, Cu or an alloy thereof. Alternatively, the circuit layer 16 can be a transparent conducting oxide (TCO), such as Indium Tin Oxides (ITO), Ga-doped ZnO (GZO) or Al-doped ZnO (AZO). The circuit layer 16 can be formed on the base 10 by physical deposition method, such as sputter, Physical Vapor Deposition (PVD) or e-beam evaporation deposition. The circuit layer 16 can also be formed by chemical deposition method, such as chemical vapor deposition (CVD), electroplating chemical deposition or screen printing.

Referring back to FIG. 1, in this embodiment, the LED dies 20 are disposed in the chamber 14 of the base 10 as an array. For reducing interaction of the light of neighboring LED dies 20, a distance between neighboring LED dies 20 is not less than 500 μm, preferably not less than 900 μm, and more preferably not less than 1000 μm. Each of the LED dies 20 has a length not larger than 350 μm, and a thickness not larger than 200 μm. Preferably, the length of the LED die 20 is not larger than 300 μm, and the thickness is not larger than 150 μm. Particularly, the length of the LED die 20 is not larger than 250 μm, and the thickness of the LED die 20 is not larger than 100 μm.

The LED die 20 can be a phosphide represented by general formula AlₓIn_{y}Ga_{(1-x-y)}P, here 0≦x≦1, 0≦y≦1 and x+y≦1; or an arsenide represented by general formula AlₓIn_{y}Ga_{(1-x-y)}As, here 0≦x≦1, 0≦y≦1 and x+y≦1. The LED die 20 can also be made of a semiconductor material capable of emitting light of a wavelength which can excite fluorescent material, for example, the LED die 20 can be of an oxide such as ZnO, or a nitride such as GaN. The LED die 20 is preferably made of a nitride semiconductor material represented by general formula InₓAl_{y}Ga_{(1-x-y)}N, here 0≦x≦1, 0≦y≦1 and x+y≦1, which can emit light of short wavelengths ranged from ultraviolet light to red light to excite fluorescent material.

Each of the LED dies 20 includes a substrate 22, a P-N junction 24 formed on the substrate 22, and P-type and N-type electrodes 26. In this embodiment, the LED dies 20 and the circuit layer 16 on the base 10 are alternately arranged along a transverse direction of the LED module 100 (particularly see FIG. 2). The substrate 22 of the LED die 20 is in direct mechanical contact with the base 10, and thus the heat generated by the LED die 20 can be directly transferred to the base 10 for dissipation. The P-type and N-type electrodes 26 both are formed on the P-N junction 24, and are electrically connected to the circuit layer 16 through wire bonding.

The substrate 22 of the LED die 20 can be an intrinsic semiconductor or an unintentionally doped semiconductor. Particularly, the substrate 22 can be a semiconductor material, such as spinel, SiC, Si, ZnO, GaN, GaAs, GaP or AlN. The substrate 22 can also be a material with good thermal conductivity but poor electrical conductivity, such as diamond. A thermal expansion coefficient of the substrate 22 of the LED die 20 is adjacent to that of the base 10. A carrier concentration of the substrate 22 is preferably 2×10⁶ cm⁻³ or lower, so that the electric current can be electrically insulated from flowing through the substrate 22 to the base 10.

To reduce thermal resistance between the base 10 and the LED dies 20, a layer of Ag epoxy 50 is applied between the substrate 22 of each of the LED dies 20 and the base 10. Alternatively, in other embodiments, thermal grease can be applied between the LED dies 20 and the base 10. Further, the LED die 20 can be combined to the base 10 through eutectic bonding. A metal selected to combine the LED die 20 and the base 10 can be Au, Sn, In, Al, Ag, Bi, Be, or an alloy thereof.

The packaging structure 30 is filled in the chamber 14 of the base 10, and encapsulates the LED dies 20 and the circuit layer 16, thereby firmly secure the LED dies 20 in place. The packaging structure 30 is generally made of transparent material, such as silicone, epoxy resin, low temperature melt glass, polymethyl methacrylate, polymer, polycarbonate, and etc. The packaging structure 30 can be formed by injecting, and can have various shapes according to needs. In this embodiment, the packaging structure 30 is within the chamber 14 of the base 10, and has a flat top surface 32 coplanar with the top side 12 of the base 10. For changing a wavelength of the light emitted by the LED die 20, fluorescence material, such as sulfides, aluminates, oxides, silicates, or nitrides, are distributed in the packaging structure 30.

The poles 40 are formed on the top side 12 of the base 10 and exposed out of the packaging structure 30. Each of the poles 40 has one end electrically connected to the circuit layer 16 and the other end configured for connecting a power source. The poles 40 can be made of Ni, Au, Sn, Be, Al, In, Ti, Ta, Ag, Cu or an alloy thereof. The poles 40 can also be made of TCO, such as ITO, GZO or AZO.

During operation of the LED module 100, the two poles 40 are electrically connected to negative and positive poles of the power source, respectively, thereby supplying electric current to the LED dies 20. Generally, the electric current is not larger than 50 mA, and has a density not larger than 50 A/cm². Preferably, the electric current is not larger than 30 mA, and a density thereof is not larger than 40 A/cm². Particularly, the electric current is not larger than 20 mA, and a density thereof is not larger than 30 A/cm².

When the LED dies 20 emit light, heat is also generated. As the LED dies 20 are maintained in direct mechanical contact with the base 10, the heat of the LED dies 20 can be directly transferred to the base 10 for dissipation. Therefore, a heat resistance for transferring the heat of the LED dies 20 to the base 10 is much reduced, and the heat can be quickly and timely taken out. Accordingly, the LED dies 20 can be maintained work at a low working temperature, a stability and a life span of the LED module 100 are thus enhanced.

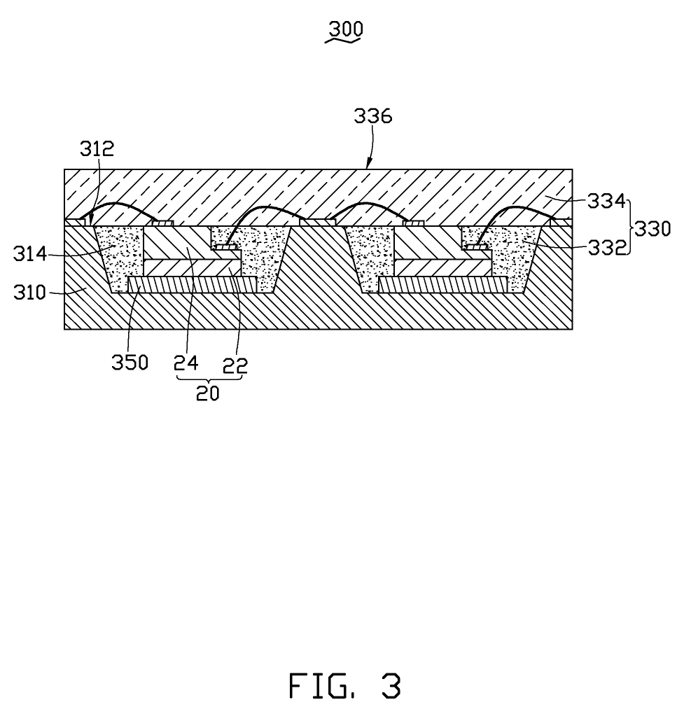

Referring to FIG. 3, an LED module 300 according to a second embodiment is shown. The LED module 300 includes a base 310 defining a plurality of grooves 314 respectively receiving a plurality of LED dies 20 therein. In this embodiment, the grooves 314 are arranged as an array. Each of the grooves 314 has a cross section expanding upwardly. A minimum of the cross section of the groove 314, i.e., a cross section at the bottom of the groove 314, is larger than an area of the LED die 20.

Each LED die 20 is disposed in one corresponding groove 314 with a bottom of the substrate 22 adhered to the base 310 at the bottom of the groove 314 by an adhesive material 350, and a top of the P-N junction 24 being substantially copular with a top side 312 of the base 310. An annular gap is defined between each of the LED dies 20 and an inner surface of the base 310 surrounding the corresponding groove 314. A packaging structure 330 is provided to encapsulate the LED dies 20. The packaging structure 330 includes an inner layer 332 filled in the annular gaps between the LED dies 20 and the base 310 and an outer layer 334 on the top side 312 of the base 310. In this embodiment, the outer layer 334 has a flat outer surface 336 substantially parallel to the top side 312 of the base 310, and has fluorescence material distributed therein.

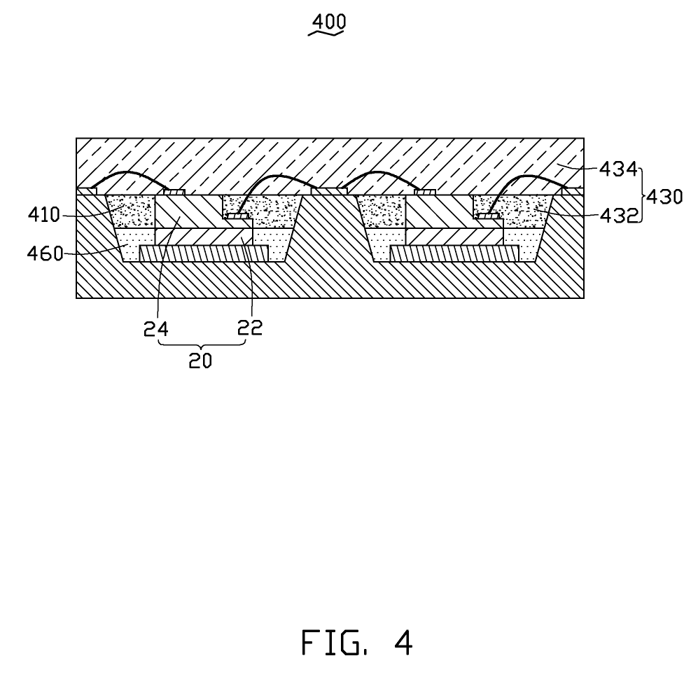

FIG. 4 shows an LED module 400 according to a third embodiment. The LED module 400 includes a base 410 receiving a plurality of LED dies 20 therein, and a packaging structure 430 encapsulating the LED dies 20. In this embodiment, an inner layer 432 of the packaging structure 430 is filled between P-N junctions 24 of the LED dies 20 and upper portions of inner surfaces of the base 410 corresponding to the P-N junctions 24. An outer layer 434 of the packaging structure 430 is on the inner layer 432, and has fluorescence material distributed therein. In addition, a thermal grease 460 is filled between substrates 22 of LED dies 20 and lower portions of the inner surfaces of the base 410 corresponding to the substrates 22. The thermal grease 460 is electric insulating, for enhancing heat transfer from the LED dies 20 to the base 410.

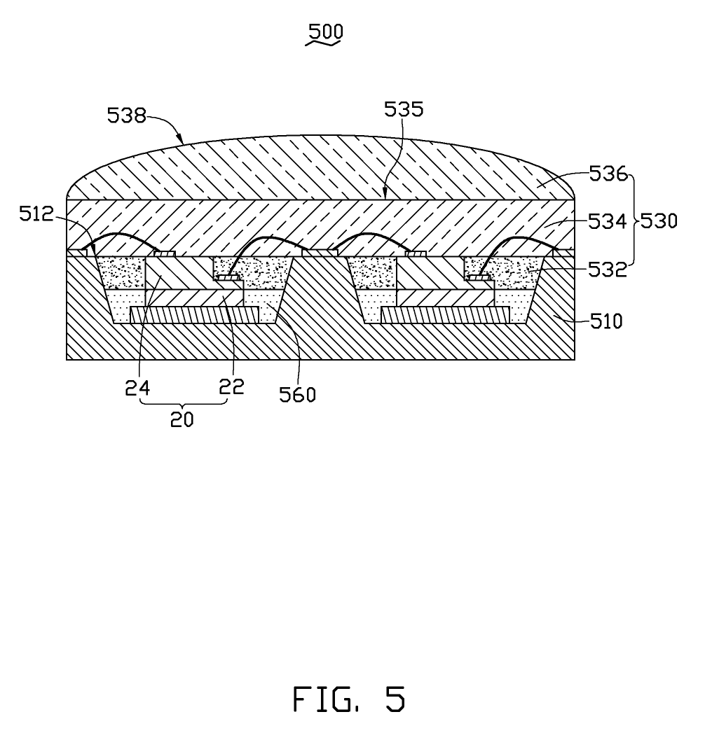

Referring to FIG. 5, an LED module 500 according to a fourth embodiment includes a base 510 receiving a plurality of LED dies 20 therein, and a packaging structure 530. The packaging structure 530 includes an inner layer 532, an outer layer 536 and a middle layer 534 between the inner layer 532 and the outer layer 536. The inner layer 532 is filled between P-N junctions 24 of the LED dies 20 and upper portions of inner surfaces of the base 510. The middle layer 534 is on a top side 512 of the base 510 and has a flat outer surface 535. The outer layer 536 is on the outer surface 535 of the middle layer 534, and has a convex outer surface 538. Fluorescence material is distributed in the outer layer 536, and dispersant is distributed in the middle layer 534. A thermal grease 560 is filled between substrates 22 of the LED dies 20 and lower portions of the inner surfaces of the base 510 corresponding to the substrates 22.

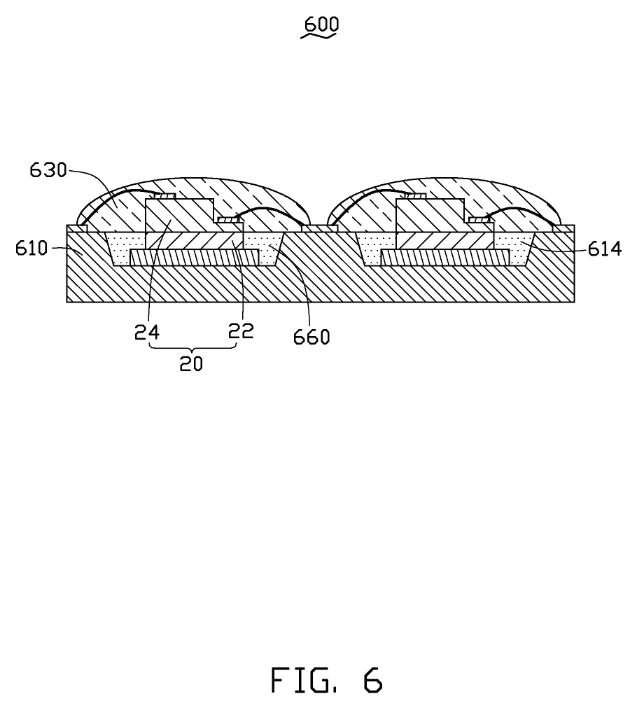

Referring to FIG. 6, an LED module 600 according to a fifth embodiment includes a plurality of LED dies 20 respectively received in grooves 614 of a base 610, and a packaging structure 630. The packaging structure 630 includes a plurality of individual packaging bodies respectively encapsulating the LED dies 20. The LED dies 20 are arranged in such a manner that substrates 22 of the LED dies 20 are entirely received in the grooves 614, while P-N junctions 24 of the LED dies 20 protrude out of the base 610. A thermal grease 660 is filled between the substrates 22 of the LED dies 20 and inner surfaces of the base 610 for enhancing heat transfer from the LED dies 20 to the base 610.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED module, comprising:
an electrically insulating ceramic base with a circuit layer directly coated thereon;
a plurality of LED dies directly fixed on the base and electrically connected to the circuit layer; and
a packaging structure encapsulating the LED dies.

2. The LED module of claim 1, wherein the base is one of Si₃N₄, SiC, ZrO₂, B₄C, TiB₂, AlxOy, AlN, BeO and Sialon.

3. The LED module of claim 1, wherein the LED dies and the circuit layer are alternating, each LED die comprising a substrate in mechanical contact with the base, a P-N junction formed on the base, and electrodes formed on the P-N junction, the electrodes being electrically connected to the circuit layer by wires.

4. The LED module of claim 1, wherein a chamber is concaved from a top side of the base receiving the plurality of LED dies and the packaging structure therein, an outer surface of the packaging structure being flat and coplanar with the top side of the base.

5. The LED module of claim 1, wherein the base defines a plurality of grooves respectively receiving the LED dies therein.

6. The LED module of claim 5, wherein a cross section of each of the grooves is larger than an area of the LED die, the LED die comprising a substrate and a P-N junction formed on the substrate, an annular gap being defined between the substrate and the base with a thermal grease filled therein.

7. The LED module of claim 6, wherein the P-N junction protrudes out of the base.

8. The LED module of claim 7, wherein the packaging structure comprises a plurality of packaging bodies respectively encapsulating the P-N junctions of the LED dies.

9. The LED module of claim 6, wherein each P-N junction is within the corresponding groove, and the packaging structure comprises an inner layer filled between the P-N junctions and the base and an outer layer on the base with fluorescence material distributed therein.

10. The LED module of claim 6, wherein each P-N junction is within the corresponding groove, and the packaging structure comprises an inner layer filled between the P-N junctions and the base, a middle layer on the base and an outer layer on the middle layer, fluorescence material being distributed in the outer layer, dispersant being distributed in the middle layer.

11. The LED module of claim 10, wherein an outer surface of the outer layer is convex, and an outer surface of the middle layer is flat.

12. The LED module of claim 3, wherein the substrate is one of spinel, SiC, Si, ZnO, GaN, GaAs, GaP and AlN.

13. The LED module of claim 3, wherein a carrier concentration of the substrate is not larger than 2×10⁶ cm⁻³.

14. The LED module of claim 1, further comprising two poles formed on the base, the poles electrically connect the circuit layer and are exposed out of the packaging structure.

15. The LED module of claim 1, wherein a distance between neighboring LED dies is not less than 1000 μm.

16. The LED module of claim 1, wherein each of the LED dies has a length not larger than 250 μm, and a thickness not larger than 100 μm.
